(19) United States
(12) Patent Application Publication
(10) Pub. No.: US 2006/0268596 A1
(43) Pub. Date: Nov. 30, 2006

(54) Ferroelectric semiconductor memory device

(75) Inventors: Kunisato Yamaoka, Osaka (JP); Yasuo Murakuki, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/353,072

(22) Filed: Feb. 14, 2006

(30) Foreign Application Priority Data
May 31, 2005 (JP) 2005-160234

(51) Int. Cl. G11C 11/22

(52) U.S. Cl. 365/145

(57) ABSTRACT

The present invention provides a ferroelectric semiconductor memory device in which the potential of data read out from a normal cell is compared with the reference level of a reference cell so as to determine whether the readout data is the “H” data or the “L” data, wherein since the reference cell is in the relaxed state when reading out data from the normal cell for the first time, the reference cell is reset before reading out data from the normal cell. Then, data is read out from the normal cell, and then the reference cell is reset. In second and subsequent data read operations of reading out data from a normal cell of another address, the reference cell is in the reset state, whereby the reference level is the same between the first data read operation and the second or subsequent data read operation. Thus, the reference level is always kept at a predetermined constant level when data is read out from normal cells.

### CROSS REFERENCE TO RELATED APPLICATIONS

This Non-provisional application claims priority under 35 U.S.C. §119(a) on Patent Application No. 2005-160234 filed in Japan on May 31, 2005, the entire contents of which are hereby incorporated by reference.

### BACKGROUND OF THE INVENTION

The present invention relates to a ferroelectric semiconductor memory device and, more particularly, to a technique for generating the reference level.

In recent years, as the process rules becomes finer and the capacity increases, there is a shift in the type of memory cells employed in ferroelectric semiconductor memory devices, i.e., from those of a 2-transistor 2-ferroelectric capacitor type to those of a 1-transistor 1-ferroelectric capacitor type with which it is possible to realize a smaller memory size. The transistor 1-ferroelectric capacitor type requires a reference cell, in addition to a normal memory cell (hereinafter referred to as a “normal cell”), and there is increasing importance in the technique for generating the reference level in order to realize a high reliability. One conventional technique for generating the reference level in a ferroelectric semiconductor memory device is disclosed in Japanese Laid-Open Patent Publication No. 2004-55007.

The conventional ferroelectric semiconductor memory device disclosed in this publication will now be described with reference to the drawings.

FIGS. 3A to 3D show a trace on a hysteresis loop when reading out data from normal cells and reference cells in the reset state and in the relaxed state, and the relationship between the “H” level, the “L” level and the reference level in the reset state and in the relaxed state. FIG. 8 shows a configuration of a memory array of a conventional ferroelectric semiconductor memory device. FIG. 9 is a timing diagram showing an operation of the conventional ferroelectric semiconductor memory device. FIGS. 10A and 10B each schematically show a physical arrangement of normal cells and reference cells in the conventional ferroelectric semiconductor memory device, and an operation thereof.

The conventional ferroelectric semiconductor memory device will now be described with reference to FIGS. 3A to 3D, 8, 10A and 10B.

FIG. 3A shows a state where the “H” data and the “L” data are read out from a memory cell and a reference cell in the reset state, FIG. 3B shows a state where the “H” data and the “L” data are read out from a memory cell and a reference cell in the relaxed state, FIG. 3C shows the relationship between the “H” level, the “L” level and the reference level when the reference level is generated by reading out data from a reference cell in the reset state, and FIG. 3D shows that when the reference level is generated by reading out data from a reference cell in the relaxed state.

In FIG. 8, BP denotes a bit line precharge signal, SAE denotes a sense amplifier enable signal, WL1 to WLn denote first to n-th word lines, CP1 to CPn denote first to n-th cell plate lines, RWL1 and RWL2 denote first and second reference word lines, RCP1 and RCP2 denote first and second reference cell plate lines, REQ1 and REQ2 denote first and second reference equalize signals, RDIN denotes “H” data reset data, XRDIN denotes “L” data reset data, RST denotes a reference reset signal, BL1 to BL8m (where m is an integer) denote first to 8m-th bit lines, 11 denotes a cell plate driver circuit, 12 denotes reference cell control circuit, 13 denotes a sense amplifier and bit line precharge control circuit, 14 denotes a sense amplifier and bit line precharge circuit, 15 denotes a peripheral circuit, 16 denotes a row decoder circuit, 17 denotes a an 8-bit normal cell array, 18 denotes reference cells for 8 bit lines, T1 to T7 denote first to seventh MOS transistors, and C1 to C4 denote first to fourth ferroelectric capacitors.

The gate of the first MOS transistor T1 is connected to the first word line WL1, the drain thereof is connected to the first bit line BL1, the source thereof is connected to the first electrode of the first ferroelectric capacitor C1, the second electrode of the first ferroelectric capacitor C1 is connected to the first cell plate line CP1, the gate of the second MOS transistor T2 is connected to the first word line WL1, the drain thereof is connected to the fourth bit line BL4, the source thereof is connected to the first electrode of the second ferroelectric capacitor C2, and the second electrode of the second ferroelectric capacitor C2 is connected to the first cell plate line CP1. Moreover, the gate of the fifth MOS transistor T5 is connected to the first reference equalize signal REQ1, the drain thereof is connected to the second bit line BL2, the source thereof is connected to the third bit line BL3, the gate of the sixth MOS transistor T6 is connected to the reference reset signal RST, the drain thereof is connected to the first electrode of the third ferroelectric capacitor C3, the source thereof is connected to the “L” data reset data XRDIN, the second electrode of the third ferroelectric capacitor C3 is connected to the first reference cell plate line RCP1, the gate of the seventh MOS transistor T7 is connected to the reference reset signal RST, the drain thereof is connected to the first electrode of the fourth ferroelectric capacitor C4, the source thereof is connected to the “H” data reset data RDIN, and the second electrode of the fourth ferroelectric capacitor C4 is connected to the first reference cell plate line RCP1.

In FIG. 9, BP denotes the bit line precharge signal, WL1 denotes the first word line, CP1 denotes the first cell plate line, REQ1 denotes the first reference equalize signal, RWL1 denotes the first reference word line, RCP1 denotes the first reference cell plate line, SAE denotes the sense amplifier enable signal, and BL1 to BL4 denote the first to fourth bit lines.

FIGS. 10A and 10B each schematically show a physical arrangement of normal cells and reference cells, where each unit of normal or reference cells that is accessed with one address is encircled with a border line. FIG. 10A shows a state where the normal cells and the reference cells are all in the relaxed state (each solid circle represents a cell in the relaxed state). FIG. 10B shows a state of normal cells and reference cells after accessing normal cells of a particular address (hatched portion), where each solid circle represents a cell in the relaxed state and each open circle represents an accessed cell in the reset state.

A case will be described below where the conventional ferroelectric semiconductor memory device is formed by (8×n×m) normal cells and (8×2×m) reference cells, and where the “H” data is stored in the first ferroelectric capacitor C1 and the fourth ferroelectric capacitor C4, the “L” data is stored in the second ferroelectric capacitor C2 and the third ferroelectric capacitor C3, and the normal cells and the reference cells are in the reset state. As shown in FIG. 3A, in the reset state, the “H” data is at point A and the “L” data is at point E.

The conventional ferroelectric semiconductor memory device first brings the bit line precharge signal BP to “L” at time t01 in FIG. 9, thereby bringing all of the first to 8m-th bit lines BL1 to BL8m to the floating state. Then, the conventional device brings the first reference equalize signal REQ1 to the “H” level at time t02 in FIG. 9, the first word line WL1 and the first reference word line RWL1 to the “H” level at time t03, the first cell plate line CP1 and the first reference cell plate line RCP1 to the “H” level at time t04, thereby reading out the “H” data from the first ferroelectric capacitor C1 and the fourth ferroelectric capacitor C4 in FIG. 8 and the “L” data from the second ferroelectric capacitor C2 and the third ferroelectric capacitor C3. Then, the “H” data transitions from point A in FIG. 3A to point B, and the “L” data transitions from point E to point D, thereby reading out the “H” data to the first bit line BL1, the “L” data to the fourth bit line BL4 and the reference level to the second bit line BL2 and the third bit line BL3. The gradient of the line between point M and point B and that of the line between point N and point D are equal to the bit line capacitance. The conventional device employs a scheme for generating the reference level, in which the device reads out data from two reference cells (i.e., the ferroelectric capacitors C3 and C4) while equalizing the reference cells by the fifth MOS transistor T5 of FIG. 8. Because the equalization is done in a portion where the ferroelectric capacitance of the “H” data (the tangent Csh1 at point B in FIG. 3A) and the ferroelectric capacitance of the “L” data (the tangent Csl1 at point D in FIG. 3A) are different from each other (Csh1>Csl1), it is necessary, for setting the reference level in the middle between the “H” level and the “L” level as shown in FIG. 3D, that the number x of reference cells storing the “L” data is larger than the number y of reference cells storing the “H” data.

Then, the conventional device brings the first cell plate line CP1 and the first reference cell plate line RCP1 to “L” at time t05 in FIG. 9, the first reference word line RWL1 to “L” at time t06, and the first reference equalize signal REQ1 to “L” at time t07, and amplifies the readout data at time t09 by a sense amplifier (not shown).

At time t10, as the first cell plate line CP1 and the first reference cell plate line RCP1 are brought to “H”, the normal cells and the reference cells are overwritten (reset) with the “L” data. At time t11, as the first reference cell plate line RCP1 is brought to “L”, the reference cells are overwritten with the “H” data. At time t12, as the first cell plate line CP1 is brought to “L”, the normal cells are overwritten (reset) with the “H” data. Finally, the device brings the bit line precharge signal BP to “H” and the sense amplifier enable signal SAE to “L” at time t14, and the first word line WL1 to “L” at time t16, thus completing the operation.

After data have been written to and stored in the normal cells and the reference cells and the cells have transitioned to the relaxed state, the conventional ferroelectric semiconductor memory device operates as follows.

The “H” data of the normal cells and the reference cells is at point P in FIG. 3B, and the “L” data is at point Q in FIG. 3B. When data is read out from the normal cells and the reference cells, the “H” data transitions from point P to point G and the “L” data transitions from point Q to point J, thereby reading out the charge in accordance with the ferroelectric capacitances at the tangent Csh2 at point G and the tangent Csl2 at point J, and the reference level is generated by equalizing all of the first to 8m-th bit lines BL1 to BL8m of FIG. 8. In the relaxed state, the tangent Csh2 at point G<the tangent Csh1 at point B, the tangent Csl2 at point J>the tangent Csl1 at point D, and the number x of reference cells storing the “L” data is larger than the number y of reference cells storing the “H” data, whereby the reference level is shifted to the “H” data side from the level in the middle between the “H” level and the “L” level in the relaxed state (indicated by a dotted line), as shown in FIG. 3D. If the number y of the “H” data and the number x of the “L” data are equal to each other, the reference level will be in the middle between the “H” level and the “L” level in the relaxed state (indicated by the dotted line).

However, the conventional ferroelectric semiconductor memory device has a problem in that the reference level in the first data read operation of reading out data from normal cells is different from that in the second and subsequent data read operations. This will now be discussed in detail.

Referring to FIG. 9, after data have been written to and stored in the normal cells and the reference cells and the cells have transitioned to the relaxed state, the conventional ferroelectric semiconductor memory device operates as follows. When reading out data from an address, the data read operation is performed under the relationship between the “H” level, the “L” level and the relaxed reference level of the normal cells in the relaxed state as shown in FIG. 3D.

However, after the data read operation, the normal cells and the reference cells from which data have been read out both return to the reset state. Therefore, when reading out data from normal cells of the next address, the “H” level and the “L” level of the normal cells from which the data is read out will be as shown in FIG. 3D, whereas the reference level will be as shown in FIG. 3C, thus failing to achieve the reference level of the positional relationship as shown in FIG. 3D, and the reference level will be set substantially in the middle between the “H” level and the “L” level in the relaxed state. As a result, the relationship between the “H” level, the “L” level and the reference level of normal cells from which the first data read operation is performed as shown in FIG. 3D is different from that of normal cells from which the second and subsequent data read operations are performed.

### SUMMARY OF THE INVENTION

It is therefore an object of the present invention to always keep the reference level at the same level in the first data read operation and in the second and subsequent data read operations.

In order to achieve this object, the present invention sets the reference level always based on reference cells in the reset state, in view of the fact that reference cells in the first data read operation are in the relaxed state and reference cells in the second and subsequent data read operations are in the reset state.

Specifically, a ferroelectric semiconductor memory device of the present invention includes: a large number of normal cells formed by ferroelectric memory elements; a reference cell; a control circuit for reading out a reference level of the reference cell when reading out data of one of the large number of normal cells; and a sense amplifier for amplifying a potential difference between a potential of the data read out from the normal cell and the reference level of the reference cell, wherein the control circuit sets the reference level to a predetermined potential, the predetermined potential being between a potential read out from the reference cell storing a high-potential data and a potential read out from the reference cell storing a low-potential data when a difference between the potential of the high-potential data and the potential of the low-potential data is at maximum based on conditions of the reference cell, and the predetermined potential being greater than or equal to a sensitivity of the sense amplifier.

In one embodiment of the present invention, a plurality of reference cells are provided; and the control circuit generates the reference level by equalizing two or more of the plurality of reference cells.

In one embodiment of the present invention, the control circuit varies the reference level by varying a ratio between the number of reference cells storing high-potential data and the number of reference cells storing low-potential data.

In one embodiment of the present invention, the ratio between the number of reference cells storing the high-potential data and the number of reference cells storing the low-potential data is stored in a non-volatile memory or a latch circuit, other than a ferroelectric memory element, or set by using physical or electrical fuses.

In one embodiment of the present invention, the control circuit resets all of the reference cells before accessing one or more of the large number of normal cells.

In one embodiment of the present invention, for the operation of resetting all of the reference cells before accessing the normal cells, the control circuit sets a reset time to be shorter than a data write time for the normal cells.

In one embodiment of the present invention, the control circuit does not overwrite data to the reference cell after accessing the normal cells.

In one embodiment of the present invention, the control circuit overwrites data to the reference cell after accessing the normal cells.

In one embodiment of the present invention, the reference cell is formed by a paraelectric capacitor.

Thus, with the ferroelectric semiconductor memory device of the present invention, in the first normal cell data read operation and in the second and subsequent normal cell data read operations, the reference level of the reference cell is at the same level, e.g., the reference level of a normal cell (ferroelectric element) in the reset state. Therefore, in the first data read operation and in the second and subsequent data read operations, the readout data is determined to be either the H data or the L data always with respect to the same reference level.

Particularly, in the present invention, although the voltage application period for which the voltage is applied to a ferroelectric capacitor needs to be set while taking the retention into account for data write operations of writing data to normal cells, the voltage application period for a reference cell can be set to be the minimum voltage application period with which the ferroelectric capacitor of the reference cell can be reset because the reference cell is reset before accessing the normal cells. Thus, the voltage application period can be set to be shorter than that for the ferroelectric capacitors of the normal cells, whereby even in a case where a single reference cell is provided for a plurality of normal cells, the total stress application time for the reference cell can be set to a similar level to that for the normal cells.

### BRIEF DESCRIPTION OF THE DRAWINGS

FIG. 1 shows a configuration of a memory array provided in a ferroelectric semiconductor memory device according to a first embodiment and a second embodiment of the present invention.

FIG. 2 is a timing diagram showing an operation according to the first embodiment of the present invention.

FIG. 3A shows a trace on a hysteresis loop when reading out data from normal cells and reference cells in the reset state, and FIG. 3B shows that when reading out data from normal cells and reference cells in the relaxed state. FIG. 3C shows the relationship between the “H” level, the “L” level and the reference level when reading out data from normal cells and reference cells in the reset state, and FIG. 3D shows that when reading out data from normal cells and reference cells in the relaxed state.

FIG. 4 is a timing diagram showing an operation according to the second embodiment of the present invention.

FIG. 5 shows a trace on a hysteresis loop when resetting normal cells and reference cells in the relaxed state according to the first and second embodiments of the present invention.

FIG. 6 shows a trace on a hysteresis loop when resetting reference cells according to the first and second embodiments of the present invention.

FIGS. 7A and 7B each schematically show a physical arrangement of, and an operation of, normal cells and reference cells according to the first and second embodiments of the present invention, wherein FIG. 7A shows a case where the normal cells and the reference cells are all in the relaxed state, and FIG. 7B shows a case where normal cells are in the relaxed state and the reference cells are in the reset state.

FIG. 8 shows a configuration of a memory array of a conventional ferroelectric semiconductor memory device.

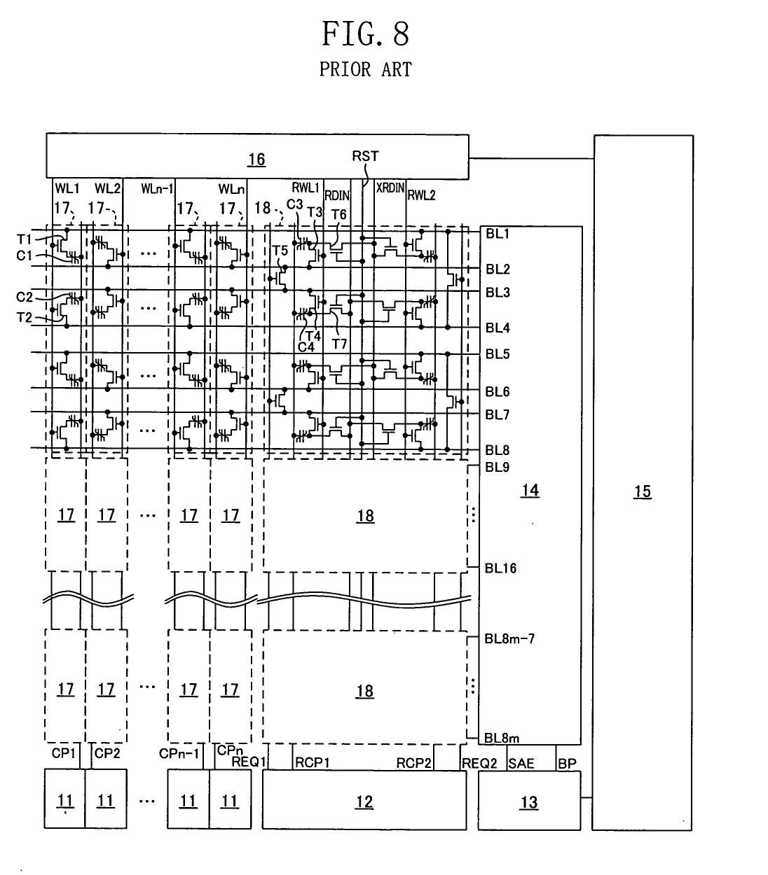

FIG. 9 is a timing diagram showing an operation of the conventional ferroelectric semiconductor memory device.

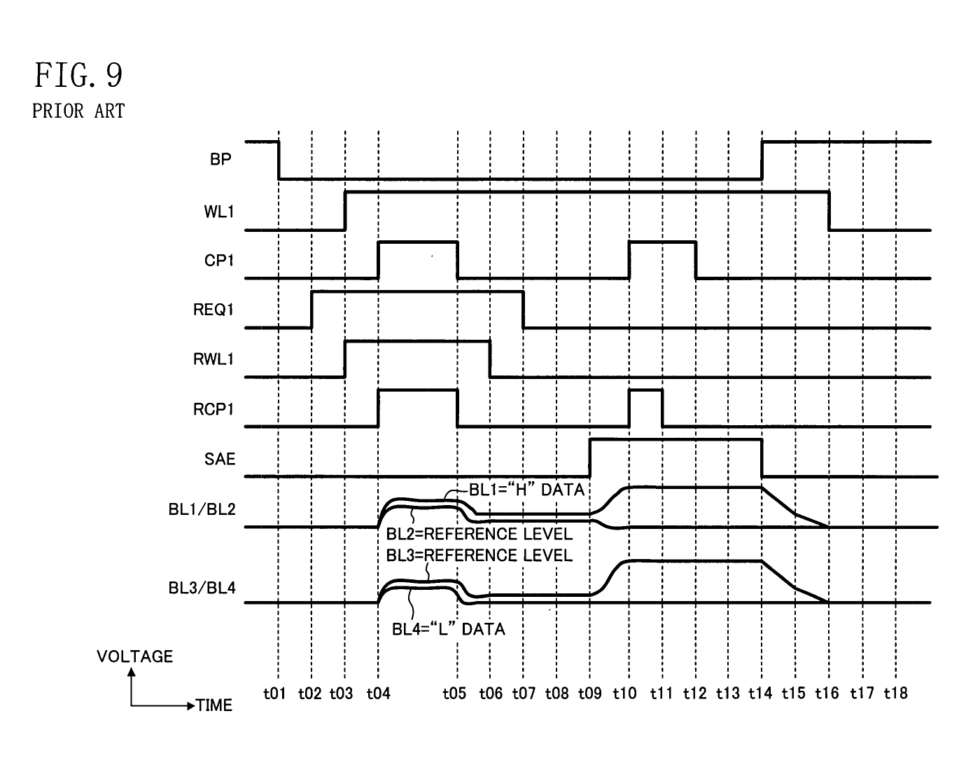

FIGS. 10A and 10B each schematically show a physical arrangement of, and an operation of, normal cells and reference cells of the conventional ferroelectric semiconductor memory device, wherein FIG. 10A shows a case where the normal cells and the reference cells are all in the relaxed state, and FIG. 10B shows a case where accessed normal cells and all the reference cells are in the reset state and the rest of the normal cells are in the relaxed state.

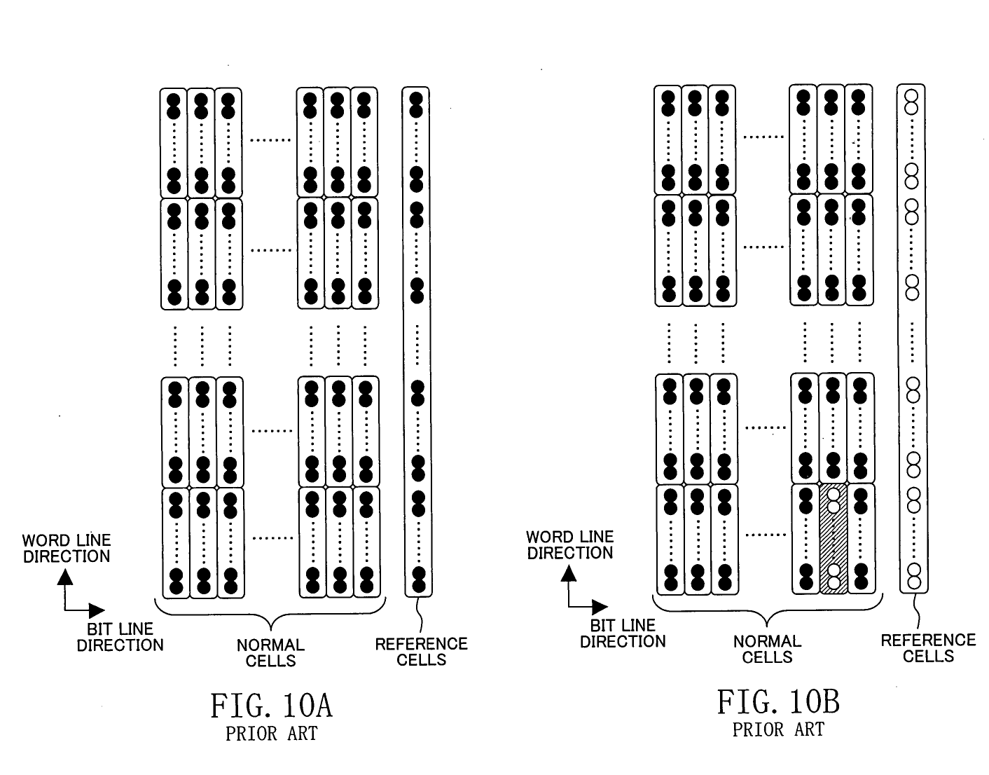

### DETAILED DESCRIPTION OF THE INVENTION

Preferred embodiments of the present invention will now be described with reference to the accompanying drawings.

### First Embodiment

A ferroelectric semiconductor memory device according to a first embodiment of the present invention will now be described.

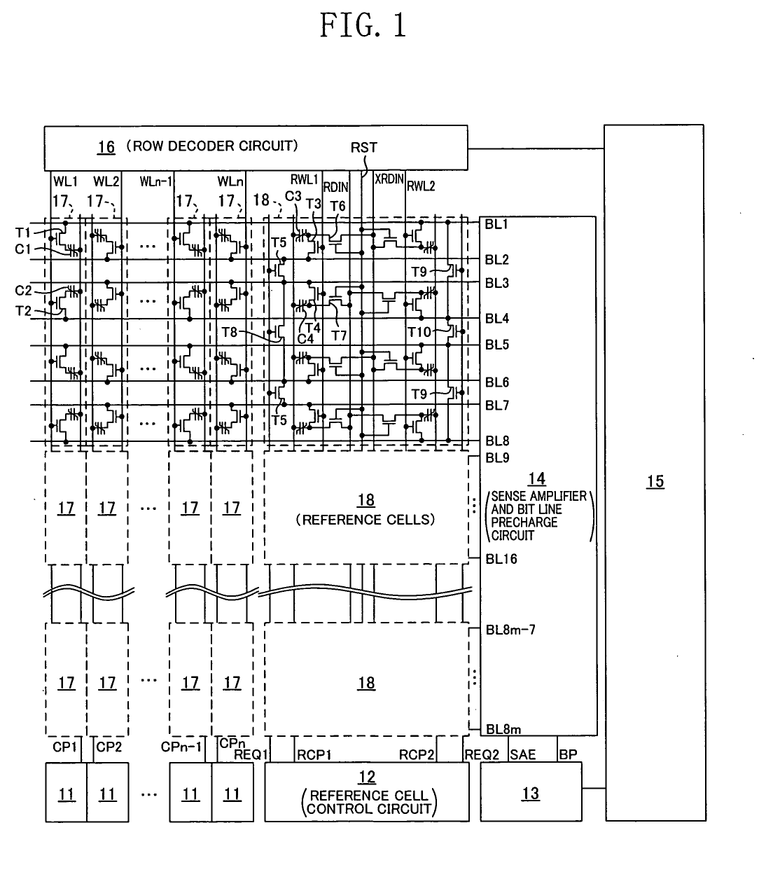

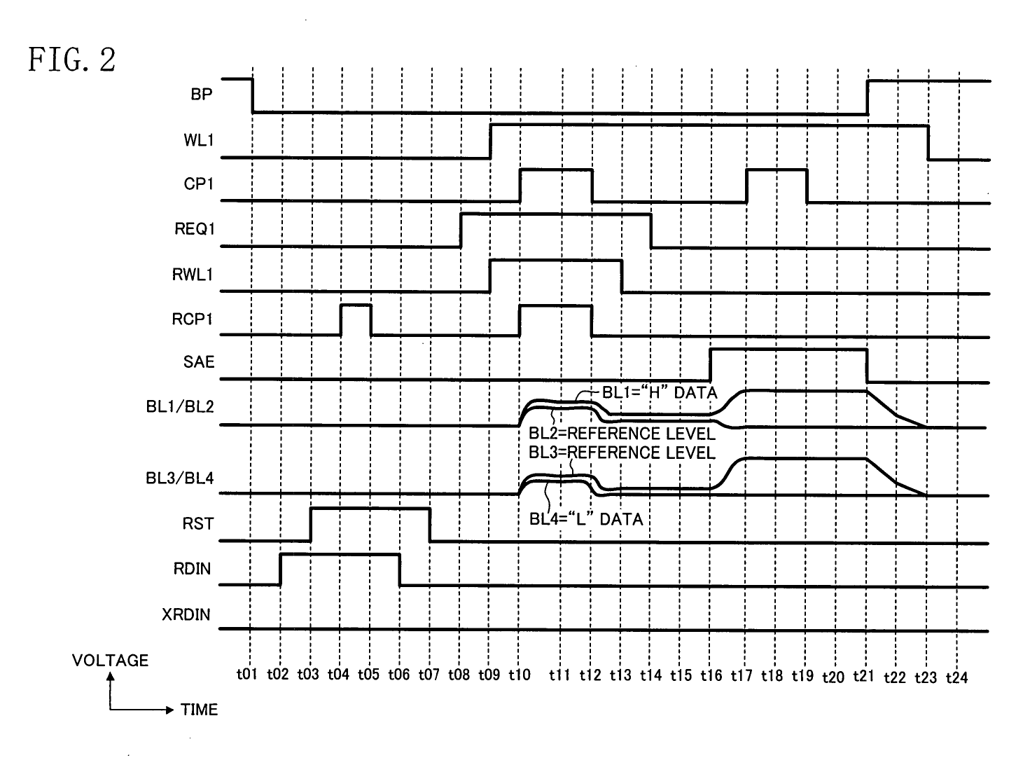

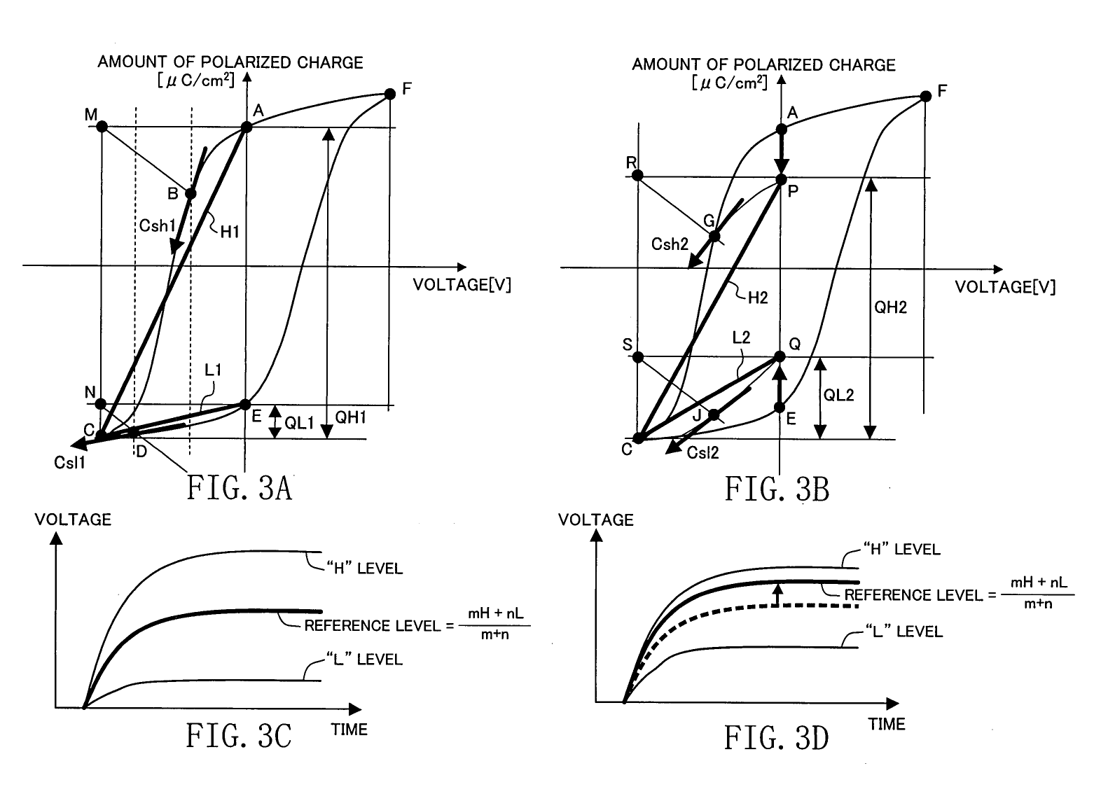

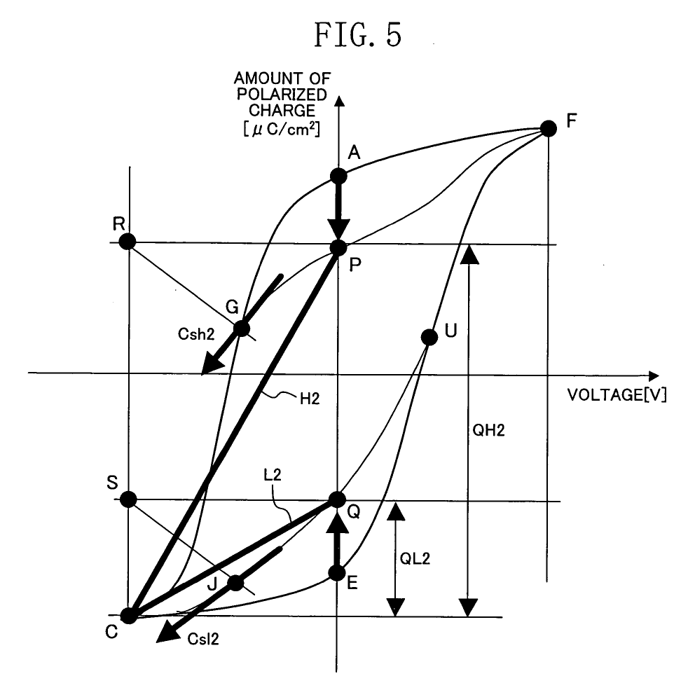

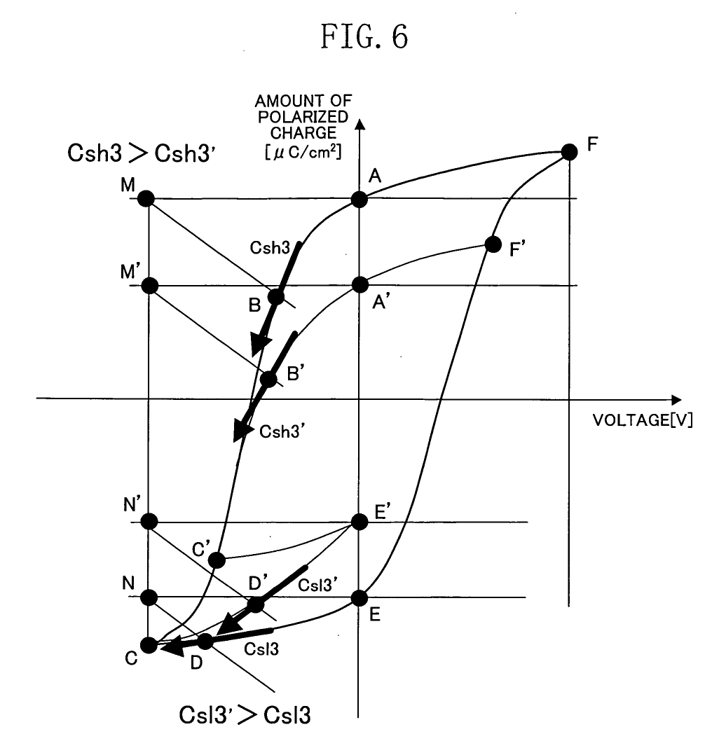

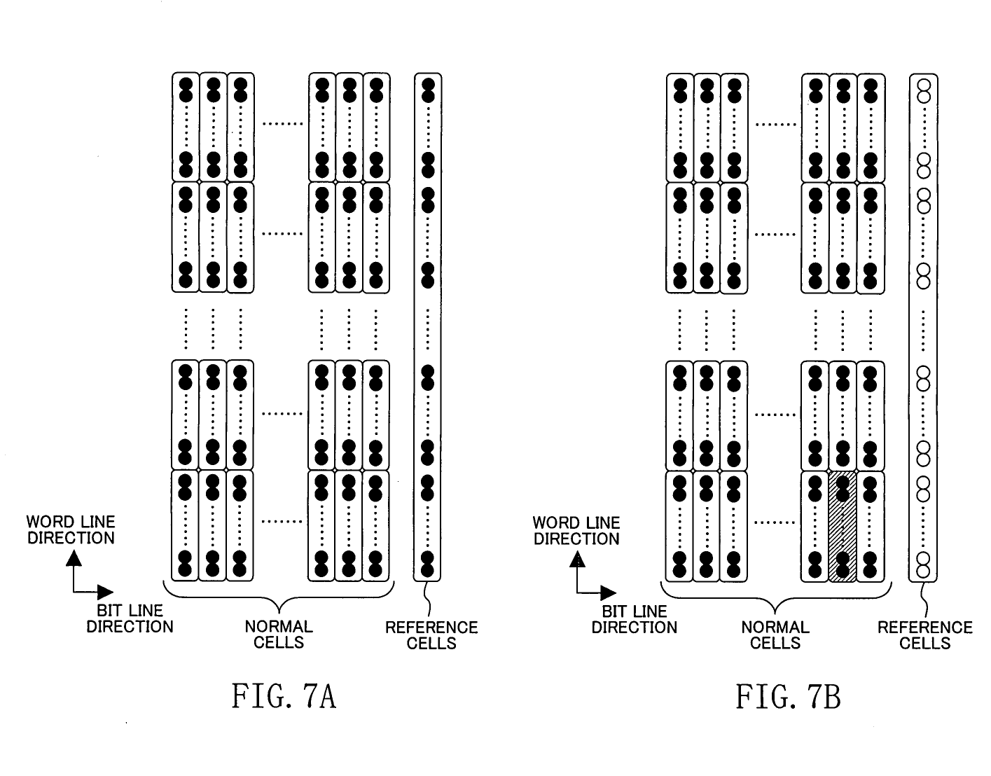

FIG. 1 shows a configuration of a memory array according to the first embodiment of the present invention. FIG. 2 is a timing diagram showing an operation according to the first embodiment of the present invention. FIGS. 3A to 3D show a trace on a hysteresis loop when reading out data from normal cells (ferroelectric memory elements) and reference cells in the reset state and in the relaxed state, and the relationship between the “H” level, the “L” level and the reference level in the reset state and in the relaxed state. FIG. 5 shows a trace on a hysteresis loop when resetting normal cells and reference cells in the relaxed state according to the first and second embodiments of the present invention. FIG. 6 shows a trace on a hysteresis loop when resetting reference cells according to the present embodiment. FIGS. 7A and 7B each schematically show a physical arrangement of, and an operation of, normal cells and reference cells according to the present embodiment.

First, the ferroelectric semiconductor memory device of the present embodiment will be described with reference to FIGS. 1 to 3D and 5 to 7B.

In FIG. 1, BP denotes a bit line precharge signal, SAE denotes a sense amplifier enable signal, WL1 to WLn denote first to n-th word lines, CP1 to CPn denote first to n-th cell plate lines, RWL1 and RWL2 denote first and second reference word lines, RCP1 and RCP2 denote first and second reference cell plate lines, REQ1 and REQ2 denote first and second reference equalize signals, RDIN denotes “H” data reset data, XRDIN denotes “L” data reset data, RST denotes a reference reset signal, BL1 to BL8m (where m is an integer) denote first to 8m-th bit lines, 11 denotes a cell plate driver circuit, 12 denotes reference cell control circuit, 13 denotes a sense amplifier and bit line precharge control circuit, 14 denotes a sense amplifier and bit line precharge circuit, 15 denotes a peripheral circuit, 16 denotes a row decoder circuit, 17 denotes a an 8-bit normal cell array, and 18 denotes reference cells for 8 bit lines. The reference cell control circuit 12 and the row decoder circuit 16 together form a control circuit for reading out the reference level of a large number of reference cells 17.

Moreover, T1 to T7 denote first to seventh MOS transistors, and C1 to C4 denote first to fourth ferroelectric capacitors, wherein the gate of the first MOS transistor T1 is connected to the first word line WL1, the drain thereof is connected to the first bit line BL1, the source thereof is connected to the first electrode of the first ferroelectric capacitor C1, the second electrode of the first ferroelectric capacitor C1 is connected to the first cell plate line CP1, the gate of the second MOS transistor T2 is connected to the first word line WL1, the drain thereof is connected to the fourth bit line BL4, the source thereof is connected to the first electrode of the second ferroelectric capacitor C2, and the second electrode of the second ferroelectric capacitor C2 is connected to the first cell plate line CP1.

Moreover, the gate of the fifth MOS transistor T5 is connected to the first reference equalize signal REQ1, the drain thereof is connected to the second bit line BL2, the source thereof is connected to the third bit line BL3, the gate of the sixth MOS transistor T6 is connected to the reference reset signal RST, the drain thereof is connected to the first electrode of the third ferroelectric capacitor C3, the source thereof is connected to “L” data reset data, the second electrode of the third ferroelectric capacitor C3 is connected to the first reference cell plate line RCP1, the gate of the seventh MOS transistor T7 is connected to the reference reset signal RST, the drain thereof is connected to the first electrode of the fourth ferroelectric capacitor C4, the source thereof is connected to “H” data reset data, and the second electrode of the fourth ferroelectric capacitor C4 is connected to the first reference cell plate line RCP1. Moreover, the gate of the eighth MOS transistor T8 is connected to the first reference equalize signal REQ1, the drain thereof is connected to the source of the fifth MOS transistor T5 (i.e., the third bit line BL3), and the source thereof is connected to the drain of the other fifth MOS transistor T5 (i.e., the sixth bit line BL6). Similarly, along the line of the second reference equalize signal REQ2, there are provided the ninth MOS transistor T9, which is similar to the fifth MOS transistor T5, and the tenth MOS transistor T10, which is similar to the eighth MOS transistor T8.

Moreover, in FIG. 2, BP denotes a bit line precharge signal, SAE denotes a sense amplifier enable signal, WL1 denotes a first word line, CP1 denotes a first cell plate line, RWL1 denotes a first reference word line, RCP1 denotes a first reference cell plate line, REQ1 and REQ2 denote first and second reference equalize signals, RDIN denotes “H” data reset data, XRDIN denotes “L” data reset data, RST denotes a reference reset signal, and BL1 to BL4 denote first to fourth bit lines.

FIG. 3A shows a trace on a hysteresis loop when reading out the “H” data (high-potential data) and the “L” data (low-potential data) from normal cells and reference cells in the reset state, and FIG. 3B shows a trace on a hysteresis loop when reading out the “H” data and the “L” data from normal cells and reference cells in the relaxed state. In these figures, the horizontal axis represents the voltage, and the vertical axis represents the amount of polarized charge. FIG. 3C shows the relationship between the “H” level, the “L” level and the reference level when reading out the “H” data and the “L” data from normal cells and reference cells when they are in the reset state, and FIG. 3D shows the relationship between the “H” level, the “L” level and the reference level when reading out the “H” data and the “L” data from normal cells and reference cells when they are in the relaxed state. In these figures, the horizontal axis represents the time and the vertical axis represents the voltage.

Where the ferroelectric semiconductor memory device of the present embodiment is formed by (8×n×m) normal cells and (8×2×m) reference cells, the ferroelectric semiconductor memory device operates as follows, with the “H” data stored in the first ferroelectric capacitor C1 and the fourth ferroelectric capacitor C4 and the “L” data stored in the second ferroelectric capacitor C2 and the third ferroelectric capacitor C3, after data have been written to and stored in the normal cells and the reference cells and the cells have transitioned to the relaxed state. The “H” data, which is at point A when in the reset state, is at point P and the “L” data, which is at point E when in the reset state, is at point Q, as shown in FIG. 3B, and normal cells and reference cells are all in the relaxed state as shown in FIG. 7A.

The ferroelectric semiconductor memory device of the present embodiment first brings the bit line precharge signal BP to “L” at time t01 in FIG. 2, thereby bringing all of the first to 8m-th bit lines BL1 to BL8m of FIG. 1 to the floating state. Then, the device brings the “H” data reset data RDIN to “H” at time t02 in FIG. 1, the reference reset signal RST to “H” at time t03, and the first reference cell plate line RCP1 to “H” at time t04, thereby resetting the “L” data of the reference cells. The device brings the first reference cell plate line RCP1 to “L” at time t05, thereby resetting the “H” data of the reference cells. Thus, the “H” data at point P transitions to point A via point F, and the “L” data is reset to point E via point J and point C as shown in FIG. 5, whereby the normal cells are in the relaxed state (represented by solid circles) and the reference cells are in the reset state (represented by open circles) as shown in FIG. 7B.

Then, when accessing the normal cells in the hatched portion of FIG. 7B, the device brings the first reference equalize signal REQ1 to the “H” level at time t08, the first word line WL1 and the first reference word line RWL1 to the “H” level at time t09, and the first cell plate line CP1 and the first reference cell plate line RCP1 to the “H” level at time t10, thereby reading out the “H” data from the first ferroelectric capacitor C1 and the fourth ferroelectric capacitor C4 of FIG. 1 and the “L” data from the second ferroelectric capacitor C2 and the third ferroelectric capacitor C3. Then, the “H” data transitions from point P in FIG. 3B to point G, and the “L” data transitions from point Q to point J, thereby reading out the “H” data to the first bit line BL1, the “L” data to the fourth bit line BL4, and the reference level to the second bit line BL2 and the third bit line BL3. The gradient of the line between point R and point G and that of the line between point S and point J are equal to the bit line capacitance.

The device employs a scheme for generating the reference level, in which the device reads out data from four reference cells (the ferroelectric capacitors C3 and C4) while equalizing the reference cells by the fifth and eighth MOS transistors T5 and T8 in one reference cell 18 whose internal configuration is shown in FIG. 1, and outputs one reference level commonly to four bit lines BL2, BL3, BL6 and BL7. Thus, for a total of m reference cells 18, 4m reference cells (the ferroelectric capacitors C3 and C4) are equalized, and one reference level is output commonly to 4m bit lines.

Because the equalization is done in a portion where the ferroelectric capacitance of the “H” data (the tangent Csh2 at point G in FIG. 3B) and the ferroelectric capacitance of the “L” data (the tangent Csl2 at point J in FIG. 3B) are different from each other (Csh2>Csl2), and because the ferroelectric capacitance of the “H” data of the reference cells is smaller than that in the reset state (the tangent Csh1 at point B in FIG. 3A) (Csh2<Csh1), and the ferroelectric capacitance of the “L” data of the reference cells is larger than that in the reset state (the tangent Csl1 at point D in FIG. 3A) (Csl2>Csl1), it is necessary, for setting the reference level in the middle between the “H” level and the “L” level as shown in FIG. 3D (indicated by the dotted line), that the number x of reference cells storing the “L” data is larger than that when the reference cells are in the reset state. The number y of reference cells storing the “H” data and the number x of reference cells storing the “L” data are set to optimal numbers such that there is obtained a predetermined potential, wherein the predetermined potential is between the “H” data and the “L” data when the potential difference between the “H” data and the “L” data is at the worst (largest) level, and is greater than or equal to the sensitivity of the sense amplifier.

Then, the device brings the first cell plate line CP1 and the first reference cell plate line RCP1 to “L” at time t12 in FIG. 2, the first reference word line RWL1 to “L” at time t13, and the first reference equalize signal REQ1 to “L” at time t14, and amplifies the readout data at time t16 by a sense amplifier (not shown). At time t17, as the first cell plate line CP1 is brought to “H”, the normal cells are overwritten (reset) with the “L” data. At time t19, as the first cell plate line CP1 is brought to “L”, the normal cells are overwritten with the “H” data.

Finally, the device brings the sense amplifier enable signal SAE to “L” and the bit line precharge signal BP to “H” at time t21, and the first word line WL1 to “L” at time t23, thus completing the operation.

In the ferroelectric semiconductor memory device of the present embodiment, when data is written to a normal cell, the voltage application period for which the voltage is applied to the ferroelectric capacitor should be set while taking the retention into account. However, for a reference cell, which is reset before accessing a normal cell, the voltage application period can be set to any period as long as the ferroelectric capacitor of the reference cell can be reset. Thus, the period can be set to be shorter than the voltage application period for which the voltage is applied to the ferroelectric capacitor of a normal cell. This will be discussed in detail below with reference to the timing diagram of FIG. 2 and the hysteresis loop of FIG. 6.

When a normal cell storing the “H” data is overwritten with the “L” data while taking the retention into account, the state transitions from point A of FIG. 6 to point E via point C in the period t17-t19 of FIG. 2. When a normal cell storing the “L” data is overwritten with the “H” data, the state transitions from point E of FIG. 6 to point A via point F in the period t19-t21 of FIG. 2.

On the other hand, the state of a reference cell when it is reset at time t04 in FIG. 2 depends on the data read out from a normal cell in the previous data read cycle. Where the data read out from the normal cell is the “H” data, the voltage applied to the ferroelectric capacitor of the reference cell becomes 0 V after the reference cell is amplified to the “L” data, whereby the cell is at point E of FIG. 6. Where the data read out from the normal cell is the “L” data, the voltage applied to the ferroelectric capacitor of the reference cell becomes 0 V after the reference cell is amplified to the “H” data, whereby the cell is at point A of FIG. 6. The reset time for a reference cell takes the maximum value when the reference cell to be reset to the “H” data is being at “L” and when the reference cell to be reset to the “L” data is being at “H”. In that state, if the overwriting time for a reference cell is made shorter than that for a normal cell as in the period t04-t05 in FIG. 2, the state transitions from point A of FIG. 6 to point E′ via point C′ when resetting from “H” to “L”, and the state transitions from point E of FIG. 6 to point A′ via point F′ when resetting from “L” to “H”. A data read operation from a reference cell is performed, starting from point A′ and point E′, and the ferroelectric capacitance value of the reference cell at the time of equalization is the tangent Csh3′ at point B′ and the tangent Csl3′ at point D′ of FIG. 6. As compared with the tangent Csh3 at point B and the tangent Csl3 at point D in a case where the reset time for a reference cell is equal to that for a normal cell, the tangent Csh3′ and the tangent Csl3′ are such that Csh3′<Csh3 and Csl3′>Csl3. Since the capacitance value is larger for the “L” data, it is necessary that the number x of reference cells storing the “L” data is larger than that in a case where the reset time is equal to that for a normal cell.

As described above, with the ferroelectric semiconductor memory device of the present embodiment, when generating a reference level by equalizing a plurality of reference cells, data can be read out from all the normal cells in the relaxed state by using the same reference level, which is always reset, and the voltage application period for which the voltage is applied to the ferroelectric capacitor of a reference cell can be made shorter than that for a normal cell by about two orders of magnitude, whereby the stress on the ferroelectric capacitor of a reference cell can be set to a similar level to that on the ferroelectric capacitor of a normal cell.

### Second Embodiment

A ferroelectric semiconductor memory device according to a second embodiment of the present invention will now be described with reference to the drawings.

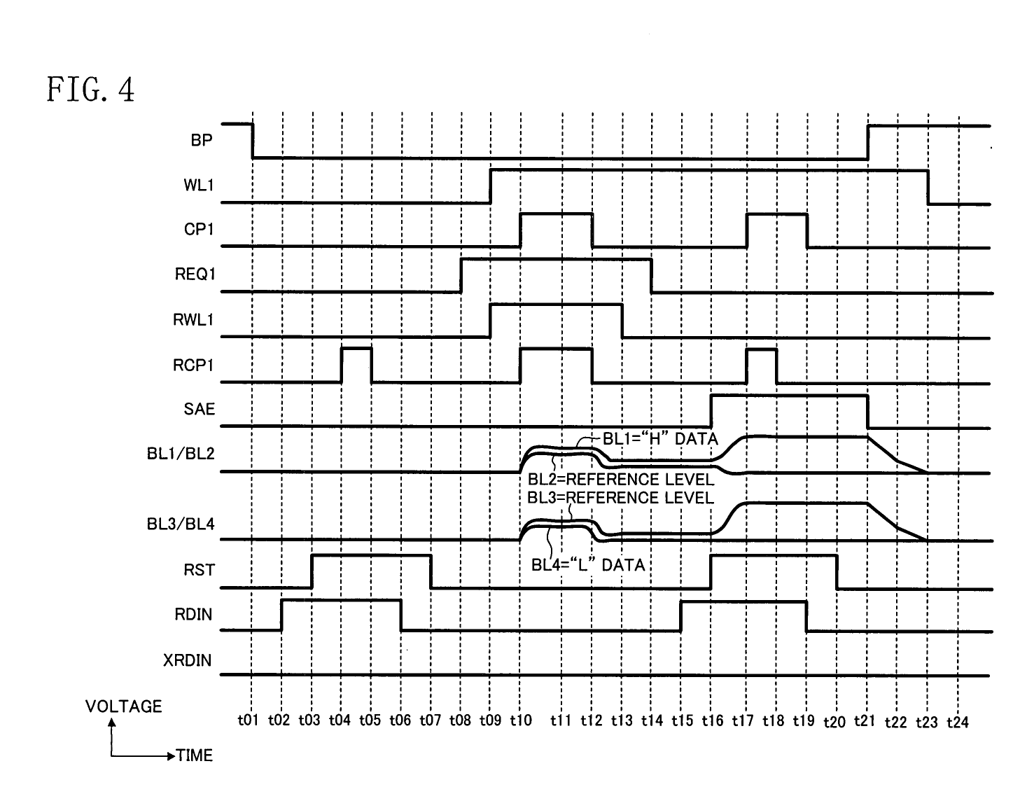

FIG. 4 is a timing diagram showing an operation according to the second embodiment of the present invention, and FIG. 6 shows a trace on a hysteresis loop when resetting reference cells according to the present embodiment.

The ferroelectric semiconductor memory device of the present embodiment will be described with reference to FIGS. 4 and 6. The present embodiment differs from the first embodiment in that the first reference cell plate line RCP1 is at “H” in the period t17-t18 in FIG. 4. The operation until time t14 in FIG. 4 is similar to that of the first embodiment, and will not be further described below.

Part of the operation of the present embodiment that differs from the first embodiment will now be described below. The device brings the “H” data reset data RDIN to “H” at time t15 in FIG. 4, the reference reset signal RST to “H” at time t16, and the first reference cell plate line RCP1 to “H” at time t17, thus resetting the “H” data of reference cells. Then, the device brings the first reference cell plate line RCP1 to “L” at time t18, thus resetting the “L” data. Then, the device brings the “H” data reset data RDIN to “L” at time t19 and the reference reset signal RST to “L” at time t20, thus completing the reset operation for the reference cells.

At this time, since the reset time for a reference cell is shorter than that for a normal cell, as in the first embodiment, the “H” data of a reference cell is at point A′ of FIG. 6 and the “L” data is at point E′ of FIG. 6 when the reset operation is completed. In the reset operation for reference cells in the period of t02-t07 of FIG. 4 in the next data read cycle, which is performed starting from the above state, the “H” data being at point A′ of FIG. 6 transitions to point A via point F, and the “L” data being at point E′ transitions to point E via point C.

As described above, with the ferroelectric semiconductor memory device of the present embodiment, the “H” data and the “L” data of the reference cells after being reset are at point A and point E of FIG. 6, respectively, as are the data of the normal cells, whereby the reference level can be more easily controlled to be in the middle between the “H” data and the “L” data of the normal cells than when the reset state of a reference cell is different from that of a normal cell as in the first embodiment. The number y of reference cells storing the “H” data and the number x of reference cells storing the “L” data are set to optimal numbers under the condition where the potential difference between the “H” data and the “L” data is at the worst level.

In the ferroelectric semiconductor memory devices of the first and second embodiments, the number y of reference cells storing the “H” data and the number x of reference cells storing the “L” data such that the reference level takes an optimal value when the readout potential difference between the “H” data and the “L” data is at the worst level are stored in some of the normal cells 17 of FIG. 1, and the optimal value can be changed based on the distribution of the normal cells and the reference cells.

Alternatively, the numbers y and x of reference cells for optimizing the reference level may be stored in a non-volatile memory or a latch circuit, other than a ferroelectric element, or may be set by using physical or electrical fuses. Then, the data reliability can be improved as compared with the case where these numbers y and x are stored in ferroelectric capacitors of normal cells.

It is understood that the present invention is applicable to cases where the reference level is generated by using paraelectric capacitors instead of using ferroelectric capacitors, and similar effects to those described above can be obtained also in such cases.

What is claimed is:

1. A ferroelectric semiconductor memory device, comprising:
a large number of normal cells formed by ferroelectric memory elements;
a reference cell;
a control circuit for reading out a reference level of the reference cell when reading out data of one of the large number of normal cells; and
a sense amplifier for amplifying a potential difference between a potential of the data read out from the normal cell and the reference level of the reference cell,
wherein the control circuit sets the reference level to a predetermined potential, the predetermined potential being between a potential read out from the reference cell storing a high-potential data and a potential read out from the reference cell storing a low-potential data when a difference between the potential of the high-potential data and the potential of the low-potential data is at maximum based on conditions of the reference cell, and the predetermined potential being greater than or equal to a sensitivity of the sense amplifier.

2. The ferroelectric semiconductor memory device of claim 1, wherein:
a plurality of reference cells are provided; and
the control circuit generates the reference level by equalizing two or more of the plurality of reference cells.

3. The ferroelectric semiconductor memory device of claim 2, wherein the control circuit varies the reference level by varying a ratio between the number of reference cells storing high-potential data and the number of reference cells storing low-potential data.

4. The ferroelectric semiconductor memory device of claim 3, wherein the ratio between the number of reference cells storing the high-potential data and the number of reference cells storing the low-potential data is stored in a non-volatile memory or a latch circuit, other than a ferroelectric memory element, or set by using physical or electrical fuses.

5. The ferroelectric semiconductor memory device of claim 2, wherein the control circuit resets all of the reference cells before accessing one or more of the large number of normal cells.

6. The ferroelectric semiconductor memory device of claim 5, wherein for the operation of resetting all of the reference cells before accessing the normal cells, the control circuit sets a reset time to be shorter than a data write time for the normal cells.

7. The ferroelectric semiconductor memory device of claim 6, wherein the control circuit does not overwrite data to the reference cell after accessing the normal cells.

8. The ferroelectric semiconductor memory device of claim 6, wherein the control circuit overwrites data to the reference cell after accessing the normal cells.

9. The ferroelectric semiconductor memory device of claim 1, wherein the reference cell is formed by a paraelectric capacitor.
